(19) United States
(12) Patent Application Publication
(10) Pub. No.: US 2015/0331732 A1
(43) Pub. Date: Nov. 19, 2015

(54) MEMORY DEVICE HAVING STORAGE FOR AN ERROR CODE CORRECTION EVENT COUNT

(71) Applicant: Rambus Inc., Sunnyvale, CA (US)

(72) Inventors: Thomas J. Giovannini, San Jose, CA (US); Kurt T. Knorpp, San Carlos, CA (US)

(73) Assignee: Rambus Inc., Sunnyvale, CA (US)

(21) Appl. No.: 14/707,348

(22) Filed: May 8, 2015

Related U.S. Application Data
(60) Provisional application No. 61/992,818, filed on May 13, 2014.
(60) Provisional application No. 62/054,885, filed on Sep. 24, 2014.

(51) Int. Cl. G06F 11/07; G11C 11/406

(52) U.S. Cl. CPC G06F 11/076; G11C 11/406; G06F 11/073; G06F 11/0787

(57) ABSTRACT

An integrated circuit memory device is disclosed. The memory device includes at least one group of storage cells. Logic derives a count of error code correction events for each of the at least one group of storage cells. Storage stores the count. A memory control interface selectively communicates the count to a memory controller.

### CROSS-REFERENCE TO RELATED APPLICATIONS

This application is a Non-Provisional that claims priority to U.S. Provisional Application No. 61/992,818, filed May 13, 2014, entitled MEMORY DEVICE HAVING STORAGE FOR AN ERROR CODE CORRECTION EVENT COUNT, and U.S. Provisional Application No. 62/054,885, filed Sep. 24, 2014, entitled MEMORY DEVICE HAVING STORAGE FOR AN ERROR CODE CORRECTION EVENT COUNT, all of which are incorporated herein by reference in their entirety.

### TECHNICAL FIELD

The disclosure herein relates to memory systems, and more specifically to memory devices, controllers and methods for varying refresh rates based on error correction information.

### BACKGROUND

Dynamic Random Access Memory (DRAM) devices undergo regular refresh operations to maintain data bit states stored in capacitive storage cells. Conventional refresh operations typically refresh all of the storage cells at the same refresh rate, regardless of the various retention rates associated with different groups of cells. Refresh operations typically consume a large percentage of the power dissipated by a DRAM.

### BRIEF DESCRIPTION OF THE DRAWINGS

Embodiments of the disclosure are illustrated by way of example, and not by way of limitation, in the figures of the accompanying drawings and in which like reference numerals refer to similar elements and in which:

FIG. 1 illustrates one embodiment of a memory system that employs variable refresh based on ECC correction events.

FIG. 2 illustrates a timing chart that contrasts first and second refresh rates for respective first and second memory banks.

FIG. 3 illustrates a flowchart that shows one example of operations carried out during the normal bank activity time interval of FIG. 2.

FIG. 4 illustrates a flowchart that shows one embodiment of an overall per-bank targeted refresh method from the perspective of the memory device of FIG. 1.

FIG. 5 illustrates a flowchart that shows the method of FIG. 4 from the perspective of the memory controller of FIG. 1.

### DETAILED DESCRIPTION

Embodiments of memory devices, associated methods and integrated circuits are disclosed herein. One embodiment of the memory device includes at least one group of storage cells. Logic derives a count of error code correction events for the at least one group of storage cells. Storage (e.g., a register) stores the count. In response to a register read command received from the memory controller, signaling interface of the memory device transmits the count to the memory controller. Refresh circuitry, responsive to the memory controller, receives refresh signals at a refresh rate for the at least one group of storage cells based on the count. By having the memory controller vary the refresh rate in response to monitored error rates in the memory device, significant power savings may be realized.

Specific embodiments described herein provide a dynamic random access memory (DRAM) with the ability to count error correction code (ECC) corrections, and to return correction counts to a memory controller (MC) using a dedicated mode register read (MRR) command. The memory controller can use correction count information to estimate bit-error rate and to determine the optimum refresh rate that will minimize power without exceeding the correction capability of the ECC. Correction counters can be provided per bank, per row sub-group, or even per row, of the memory device.

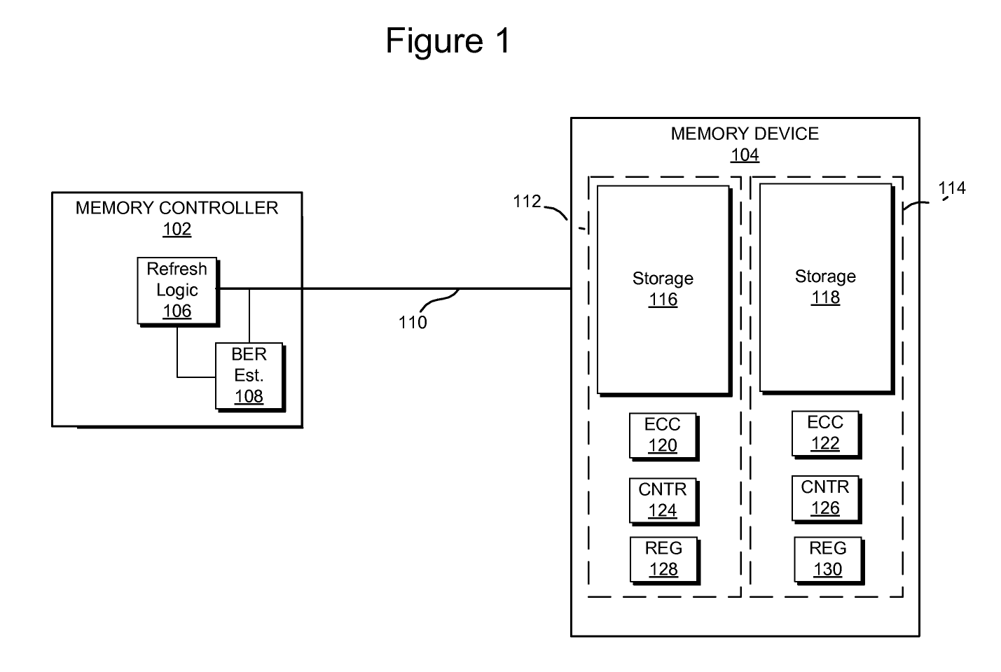

With reference to FIG. 1, a memory system, generally designated 100, is shown that includes a memory controller 102 coupled to a memory device 104 via bus 110. For one embodiment, the memory controller is a DRAM controller, with the memory device realized as a DRAM memory device. In some embodiments, the memory controller and memory device may be embodied as integrated circuits, or chips. Other embodiments may employ the memory controller as a circuit in a general purpose processor. Specific embodiments for the DRAM memory controller and memory device may be compliant with various DRAM standards, including DDR variants, low power (LPDDR) versions, and graphics (GDDR) types. Other embodiments may include multi-chip modules that, for example, employ stacked memory die, or stacked packages. Such embodiments may be used with memory modules. Additional embodiments may stack memory die and logic die together in a common package, or in separate packages stacked upon each other.

Further referring to FIG. 1, the memory controller 102 includes refresh logic 106 to generate refresh commands. The refresh commands are transmitted to the memory device 104 at a rate corresponding to a specified refresh rate. The memory device 104 generally refreshes specified groups of storage cells in response to the refresh commands at the specified refresh rate, in a manner more fully described below. The memory controller 102 also includes command generation circuitry (not shown) to generate read/write and mode register read commands for transmission to the memory device. A bit-error-rate estimator 108 couples to the refresh logic 106, and estimates error rates based on error event count values that are retrieved from the memory device 104.

With continued reference to FIG. 1, the memory device 104 includes per-bank circuitry 112 and 114 that each include groups of storage cells 116 and 118 that are, in one embodiment, organized into logical banks. The storage circuits generally include DRAM storage cells that are refreshed in response to the refresh commands sent by the memory controller 102. The per-bank circuits also include ECC encoding/decoding circuits 120 and 122, and error event counters 124 and 126. The ECC encoding/decoding circuitry may take the form of, for example, a single-error-correct double-error-detect (SEC-DED) Hamming ECC code.

Further referring to FIG. 1, a memory control interface (not shown) selectively transfers the error count value for a given bank from the register in response to, for example, a mode register read (MRR) command from the memory controller 102. Further details of this general methodology are described below. The error event counters are reset upon a refresh rate change by the memory controller via a mode register write (MRW) command, after which they increment automatically for each detected error event in the accessed decoded read data. Example events may involve actual bit error corrections and/or bit error detections. Register storage 128 and 130 for each of the groups of storage cells stores a count value generated by each counter 124 and 126. Thus, each of the per-bank circuits 112 and 114 accesses data from a respective bank, decodes any error information from the accessed read data, identifies whether a soft error was associated with the decoded data, increments the counter to generate a count value when an error is corrected and/or detected, and loads the error count value to a register.

In operation, the memory controller 102 manages “targeted refresh” operations, where the refresh commands specifying refresh rates may be varied to adjust refresh rates on a per-bank, per row sub-group, or per-row basis. Most of the discussion below focuses on an embodiment that varies refresh rates on a per-bank basis, with the understanding that variations may be employed to realize a targeted refresh methodology on a per-row sub-group or per-row basis.

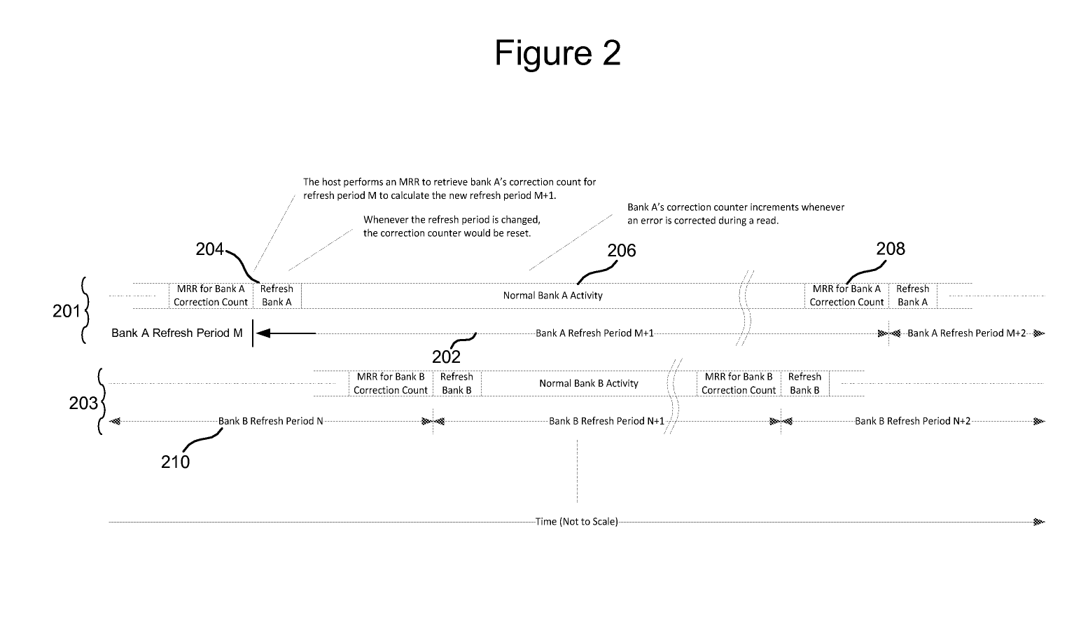

FIG. 2 illustrates an exemplary timing diagram for multiple banks of a memory device, such as that shown in FIG. 1, that are engaged in per-bank targeted refresh operations. A first portion of the diagram, at 201, shows bank operations for a first bank “Bank A” over multiple refresh periods “M”, at 202, for the bank. Each interval begins with a refresh operation, at 204, where targeted refresh commands from the memory controller are received at a targeted bank (here, Bank A) of the DRAM, and the bank storage cells are refreshed at a rate corresponding to the targeted refresh commands. Once the refresh operation is complete, normal bank activity occurs, such as accessing one or more rows of the bank for read or write operations, at 206. While not shown, normal bank activity may include correcting/detecting bit errors during memory reads and incrementing the error event counter to record the new error events. Following normal bank activity, a mode register read MRR command is received, at 208, to access a mode register that stores the error event count generated during normal bank activity, and that represents an accumulated number of errors since a last refresh rate change. The error event count value is read and transferred back to the memory controller.

Further referring to FIG. 2, a second portion of the timing diagram, at 203, shows bank operations for a second bank “Bank B” over multiple refresh periods “N”, such as at 201, that may be different than the refresh periods “M” associated with the first bank “Bank A”. As more fully explained below, the refresh periods may be adjusted such that the intervals are longer or shorter, depending on the number of corrected and/or detected errors in the error event count. Banks having storage cells with shorter retention times may be refreshed more often to reduce errors, while banks having storage cells with high retention times, and low error rates, may be refreshed at longer intervals as long as a correctable error rate is maintained.

At the memory controller, the error event count from each bank may be used as a predictor to estimate a bit-error rate (BER) associated with that bank. If the estimated BER is within an acceptable threshold level, the memory controller may adjust the refresh rate to longer intervals for that bank in an effort to save power. The adjusted rate would then take place in the targeted refresh commands to the bank for subsequent refresh operations. This per-bank granularity in refresh rate control minimizes power by limiting higher refresh rates to banks that actually need it, and reducing refresh rates to banks having storage cells with high retention times.

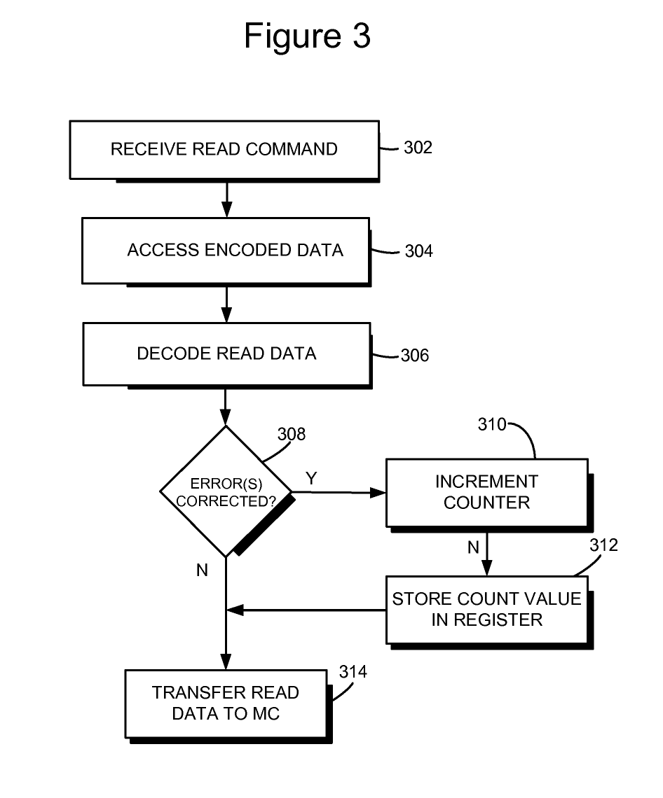

FIG. 3 illustrates a flow chart consistent with one embodiment of a set of normal bank operations, such as those shown in FIG. 2, carried out as part of an overall per-bank targeted refresh method. Assuming that the memory device supports an error correction code such as a single-error correct, double error detect (SEC-DED) Hamming ECC code, data written to a given bank is encoded via the ECC code. Upon receiving a read command, at 302, the memory device accesses the encoded read data, at 304, and decodes the data at 306. The resulting error code information, such as an error syndrome, may be used to evaluate whether any soft error correction events were associated with the read data, at 308. Assuming an SEC-DED code, if a single-bit error is corrected, then the counter is incremented, at 310. The incremented count value may also be stored in register storage, at 312. The read data is then transferred to the memory controller, at 314. The generated error event count value may then be used for a subsequent targeted refresh interval, as more fully described below. It is also possible to count double-bit/multi-bit error events, or uncorrectable error events, that are detected. This information can be used, for example, during system initialization when each memory segment is being characterized for a valid span of refresh rates. If a non-zero count is returned for a particular memory segment, the current refresh rate is too low and cannot be used during normal operation.

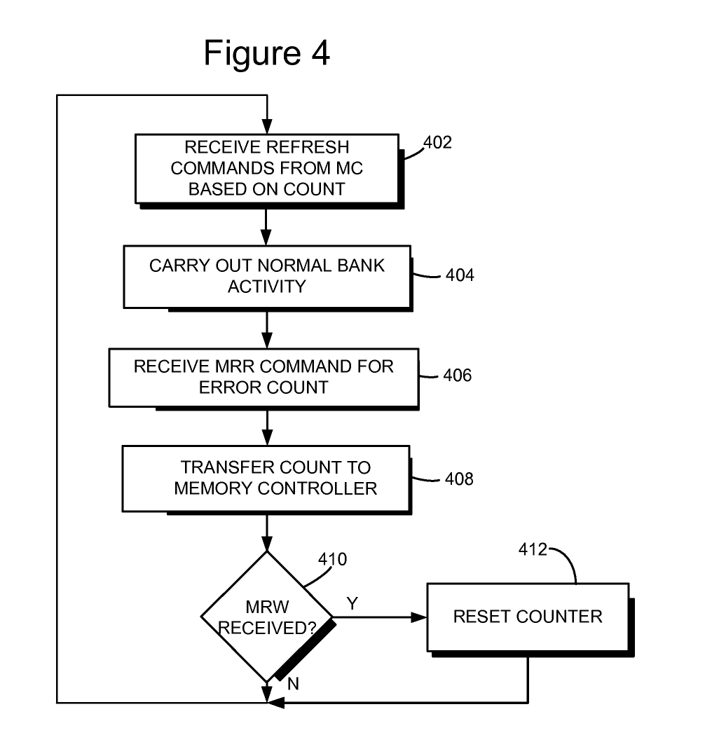

FIG. 4 illustrates one embodiment of an overall per-bank targeted refresh method consistent with the timing diagram of FIG. 2, from the perspective of a memory device. Targeted refresh commands are received from the memory controller, at 402. The targeted refresh commands are bank-specific, and correspond to a refresh rate determined by the memory controller based on evaluation of a prior error event count generated during normal bank operations, such as those shown in FIG. 3.

Further referring to FIG. 4, following the refresh operations, normal bank activity occurs, at 404. The normal bank operations may include operations such as those described in FIG. 3, including incrementing the error event counter as error events are detected, and writing the error event count value to register storage. After the normal bank activity, at 404, an MRR command is received from the memory controller to read the count value stored in the register, at 406. The count value is transferred to the memory controller, at 408, where it is evaluated to estimate a bit-error rate associated with the bank. An adjustment to the refresh rate for the bank may then be carried out. The adjustment may be made such that overall refresh power is minimized without exceeding the correction capability of the ECC. If an adjustment is made, the memory controller sends a mode register write (MRW) command, which is received by the memory device, at 410. In response to receiving the MRW command, the memory device resets the event counter, at 412, and refresh operations resume for a subsequent refresh cycle, at 402.

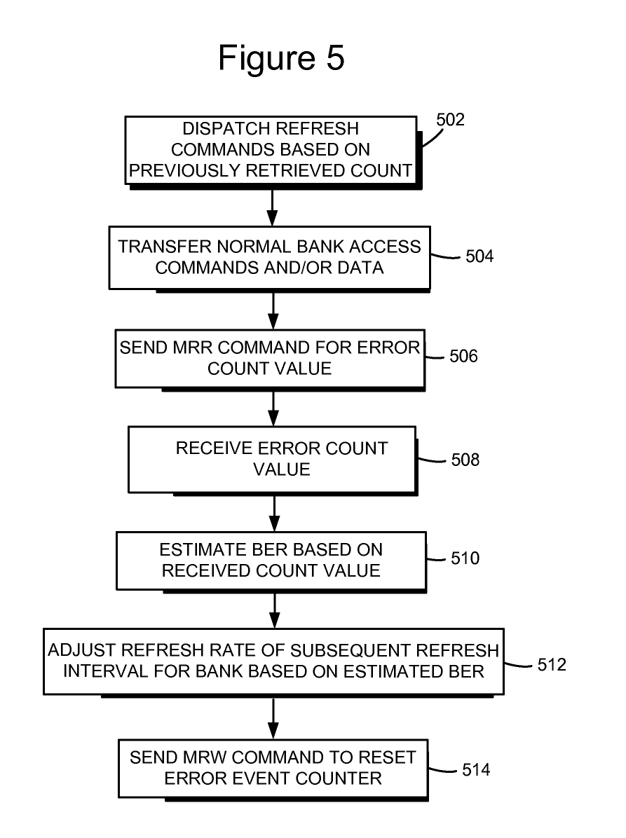

FIG. 5 is a flow chart that illustrates one embodiment of an overall per-bank targeted refresh method consistent with the timing diagram of FIG. 2, from the perspective of a memory controller. At 502, the memory controller dispatches refresh commands corresponding to a targeted refresh rate for a given bank based on a previously received error event count value from the bank. Upon completion of the refresh operation, normal bank access commands and/or data are transferred between the memory controller and the bank, at 504. At the conclusion of the normal bank operations, the memory controller issues an MRR command, at 506, to retrieve the stored error event count value from the mode register on the memory device. At 508, the error event count value is received, and utilized, at 510, to estimate a BER for the bank. The refresh rate for the bank may then be adjusted, at 512, for subsequent refresh operations such that overall refresh power is minimized without exceeding the correction capability of the ECC. Prior to changing the refresh rate for the bank, the memory controller issues an MRW to reset the bank's error event counter, at 514.

For one embodiment, the method described above also allows the memory controller to signal the need to replace a DRAM memory module prior to its failure by identifying when the module's ECC correction count trend exceeds a threshold that is representative of degraded module reliability.

The memory device and method described above provides finer-granularity targeted refresh that allows for more efficient command scheduling by the memory controller. Additionally, having a memory controller control the dynamic refresh rate per refresh target minimizes overall refresh power without compromising data reliability.

When received within a computer system via one or more computer-readable media, such data and/or instruction-based expressions of the above described circuits may be processed by a processing entity (e.g., one or more processors) within the computer system in conjunction with execution of one or more other computer programs including, without limitation, net-list generation programs, place and route programs and the like, to generate a representation or image of a physical manifestation of such circuits. Such representation or image may thereafter be used in device fabrication, for example, by enabling generation of one or more masks that are used to form various components of the circuits in a device fabrication process.

In the foregoing description and in the accompanying drawings, specific terminology and drawing symbols have been set forth to provide a thorough understanding of the present invention. In some instances, the terminology and symbols may imply specific details that are not required to practice the invention. For example, any of the specific numbers of bits, signal path widths, signaling or operating frequencies, component circuits or devices and the like may be different from those described above in alternative embodiments. Also, the interconnection between circuit elements or circuit blocks shown or described as multi-conductor signal links may alternatively be single-conductor signal links, and single conductor signal links may alternatively be multi-conductor signal links. Signals and signaling paths shown or described as being single-ended may also be differential, and vice-versa. Similarly, signals described or depicted as having active-high or active-low logic levels may have opposite logic levels in alternative embodiments. Component circuitry within integrated circuit devices may be implemented using metal oxide semiconductor (MOS) technology, bipolar technology or any other technology in which logical and analog circuits may be implemented. With respect to terminology, a signal is said to be “asserted” when the signal is driven to a low or high logic state (or charged to a high logic state or discharged to a low logic state) to indicate a particular condition. Conversely, a signal is said to be “deasserted” to indicate that the signal is driven (or charged or discharged) to a state other than the asserted state (including a high or low logic state, or the floating state that may occur when the signal driving circuit is transitioned to a high impedance condition, such as an open drain or open collector condition). A signal driving circuit is said to “output” a signal to a signal receiving circuit when the signal driving circuit asserts (or deasserts, if explicitly stated or indicated by context) the signal on a signal line coupled between the signal driving and signal receiving circuits. A signal line is said to be “activated” when a signal is asserted on the signal line, and “deactivated” when the signal is deasserted. Additionally, the prefix symbol “/” attached to signal names indicates that the signal is an active low signal (i.e., the asserted state is a logic low state). A line over a signal name (e.g., ‘ <̅s̅i̅g̅n̅a̅l̅ n̅a̅m̅e̅>̅’) is also used to indicate an active low signal. The term “coupled” is used herein to express a direct connection as well as a connection through one or more intervening circuits or structures. Integrated circuit device “programming” may include, for example and without limitation, loading a control value into a register or other storage circuit within the device in response to a host instruction and thus controlling an operational aspect of the device, establishing a device configuration or controlling an operational aspect of the device through a one-time programming operation (e.g., blowing fuses within a configuration circuit during device production), and/or connecting one or more selected pins or other contact structures of the device to reference voltage lines (also referred to as strapping) to establish a particular device configuration or operation aspect of the device. The term “exemplary” is used to express an example, not a preference or requirement.

While the invention has been described with reference to specific embodiments thereof, it will be evident that various modifications and changes may be made thereto without departing from the broader spirit and scope of the invention. For example, features or aspects of any of the embodiments may be applied, at least where practicable, in combination with any other of the embodiments or in place of counterpart features or aspects thereof. Accordingly, the specification and drawings are to be regarded in an illustrative rather than a restrictive sense.

We claim:

1. An integrated circuit memory device comprising:
at least one group of storage cells;
logic to derive a count of error code correction events for the at least one group of storage cells;
storage to store the count; and
a memory control interface to selectively communicate the count to a memory controller.

2. The integrated circuit memory device of claim 1, wherein at least one group of storage cells receive refresh commands from the memory controller at a refresh rate based on the count.

3. The integrated circuit memory device of claim 1, wherein the at least one group of storage cells comprises groups of storage cells, and the logic derives a count of error code correction events for each group of storage cells.

4. The integrated circuit memory device of claim 3, wherein at least one group of storage cells receive refresh commands from the memory controller at a refresh rate based on the count corresponding to that group.

5. The integrated circuit memory device of claim 4, wherein the refresh rate for each group of storage cells is based on the count corresponding to that group.

6. The integrated circuit memory device of claim 3, wherein each group of storage cells corresponds to a bank of storage cells, and addressable via a bank address.

7. The integrated circuit memory device of claim 1, wherein the storage comprises a mode register responsive to a Mode Register Read (MRR) command.

8. A method of operation in a memory device, the method comprising:
receiving a memory access request from a memory controller to access at least one group of storage cells;
transferring data corresponding to the request;
deriving a count of error code correction events associated with the at least one group of storage cells;
storing the count; and
selectively communicating the count to the memory controller.

9. The method of claim 8, further comprising:
receiving refresh signals for the at least one group of storage cells from the memory controller, the refresh signals to refresh the at least one group of storage cells at a refresh rate based on the count.

10. The method of claim 9, further comprising:
receiving refresh signals at a varied refresh rate based on the count exceeding a threshold error rate.

11. The method of claim 10, further comprising:
receiving a mode register write command to reset the count upon the memory controller determining a change in the refresh rate.

12. The method of claim 8, wherein the at least one group of storage cells comprises groups of storage cells, and wherein the deriving comprises deriving a count of error code correction events for each of the groups of storage cells.

13. The method of claim 12, further comprising:
receiving first refresh signals for a first group of storage cells from the memory controller, the first refresh signals to refresh the first group of storage cells at a first refresh rate based on a count associated with the first group of storage cells; and
receiving second refresh signals for a second group of storage cells from the memory controller, the second refresh signals to refresh the second group of storage cells at a second refresh rate based on a count associated with the second group of storage cells.

14. The method of claim 13, wherein the second refresh rate is different than the first refresh rate.

15. The method of claim 8, wherein storing comprises:
writing the count to register storage.

16. The method of claim 15, wherein selectively communicating the count comprises:
transferring the count from the register to the memory controller in response to a mode register read (MRR) command.

17. A method of operation in a memory device, the method comprising:
in a first refresh interval for a first group of storage cells,
receiving a register read command from a memory controller;
transferring first error count information associated with the first group of storage cells to the memory controller in response to the register read command; and
in a second refresh interval for the first group of storage cells,
receiving refresh commands from the memory controller at a first refresh rate based on the first error count information.

18. The method of claim 17, further comprising:
in a third refresh interval for a second group of storage cells,
receiving a second register read command from a memory controller;
transferring second error count information associated with the second group of storage cells to the memory controller in response to the register read command; and
in a fourth refresh interval for the second group of storage cells,
receiving refresh commands from the memory controller corresponding to a second refresh rate based on the second error count information.

19. The method of claim 18, wherein the second refresh rate is different than the first refresh rate.

20. The method of claim 18, wherein the first group of storage cells comprises a first bank of storage cells, and the second group of storage cells comprises a second bank of storage cells.
